(19) United States
(12) Patent Application Publication
(10) Pub. No.: US 2026/0196277 A1
(43) Pub. Date: Jul. 9, 2026

(54) EARLY PROGRAM TERMINATION FOR NAND SLC PROGRAM

(71) Applicant: Sandisk Technologies, Inc., Milpitas, CA (US)

(72) Inventors: Xuan Tian, Shanghai (CN); Liang Li, Shanghai (CN); Ming Wang, Shanghai (CN)

(73) Assignee: Sandisk Technologies, Inc., Milpitas, CA (US)

(21) Appl. No.: 19/012,158

(22) Filed: Jan. 7, 2025

(51) Int. Cl. G11C 16/34; G11C 16/04; G11C 16/10

(52) U.S. Cl. CPC G11C 16/3427; G11C 16/0483; G11C 16/10; G11C 16/3459

(57) ABSTRACT

Technology for handling neighbor plane disturb when programming non-volatile memory such as NAND. A memory system performs single level cell (SLC) programming with multiple program loops with verify. The memory system determines SLC programming speed during the SLC programming. The memory system terminates programming early in a plane having slow SLC programming.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

Modern storage systems such as, for example, solid state drives typically contain a number of semiconductor dies with each die containing memory cells such as NAND strings. Each die may contain one or more planes with each plane containing a large number of blocks. Each block contains a large number of memory cells such as NAND strings. A NAND string contains memory cell transistors connected in series, a drain side select gate at one end, and a source side select gate at the other end. Each NAND string is associated with a bit line. The block typically has many word lines that provide voltages to the control gates of the memory cell transistors. In some architectures, each word line connects to the control gate of one memory cell on each respective NAND string in the block. The block is associated with a source line. The source side select gates are used to connect or disconnect the NAND channels from the source line.

The memory cells are programmed one group at a time. The unit of programming is typically referred to as a page. Typically, the memory cells are programmed to a number of data states. Using a greater number of data states allows for more bits to be stored per memory cell. For example, four data states may be used to store two bits per memory cell, eight data states may be used in order to store three bits per memory cell, 16 data states may be used to store four bits per memory cell, etc. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell. At the end of a successful programming process, each memory cell's Vt should be within one of a number of Vt distributions.

Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 3C is a block diagram depicting one embodiment of a portion of column control circuitry that contains a number of read/write circuits.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells.

FIG. 4C depicts an embodiment of a stack showing a cross-sectional view along line AA of FIG. 4B.

FIG. 4D depicts a view of the region 445 of FIG. 4C.

FIG. 4E is a schematic diagram of a portion of one embodiment of a block, depicting several NAND strings.

FIGS. 5A and 5B depicts threshold voltage distributions.

FIGS. 6A, 6B, and 6C depict further details of Vt distributions during programming by an embodiment of a memory system.

FIG. 7 shows two Vt distributions for an example of programming in a good plane.

FIG. 8 shows two Vt distributions for an example of programming in a bad plane.

FIG. 9 is a flowchart of one embodiment of a process for early termination of SLC programming.

FIG. 10 is a flowchart of one embodiment of a process for early termination of SLC programming in a target plane.

FIG. 11 is a flowchart of one embodiment of a process for early termination of SLC programming in a target plane.

FIG. 12 is a flowchart of one embodiment of a process for early termination of SLC programming in a target plane.

FIG. 13 illustrates latch usage during an embodiment of SLC programming.

### DETAILED DESCRIPTION

Technology is disclosed for handling neighbor plane disturb when programming non-volatile memory such as NAND. The memory system is able to program memory cells in multiple planes on the same memory die in parallel. A problem with the programming in one of the planes can negatively impact the programming in multiple other planes. The plane that triggers the problem is referred to as the trigger plane and the other planes are referred to as the victim planes. The slow programming in a trigger plane could be due to some defect such as a current leakage issue. Not only does this defect cause very slow programming in the trigger plane, but the defect could reduce the magnitude of the program voltage in the victim planes. This reduction in program voltage in the victim planes could result in a program failure in the victim planes. A common response to a program failure is for the memory system to mark the block having the program failure as bad. Therefore, blocks in the victim planes can be marked as bad. An embodiment of a memory die contains a number of planes of memory cells. In one embodiment, the memory die has an extreme multi-plane architecture with 32, 64, 128 or some other very large number of planes. This loss of blocks is detrimental to any memory die, but for a memory die with a multi-plane architecture there is a potential for a large number of blocks to be lost in victim planes due a defect in a trigger plane.

An embodiment of a memory system performs SLC programming with multiple program loops. Therefore, neighbor plane disturb is a significant risk. An embodiment of a memory system terminates programming early in a trigger plane having slow SLC programming. This early program termination prevents negative impacts such as low programming voltage in the victim planes. Therefore, the victim planes are far more likely to successfully complete programming, thereby preventing block loss in the victim planes.

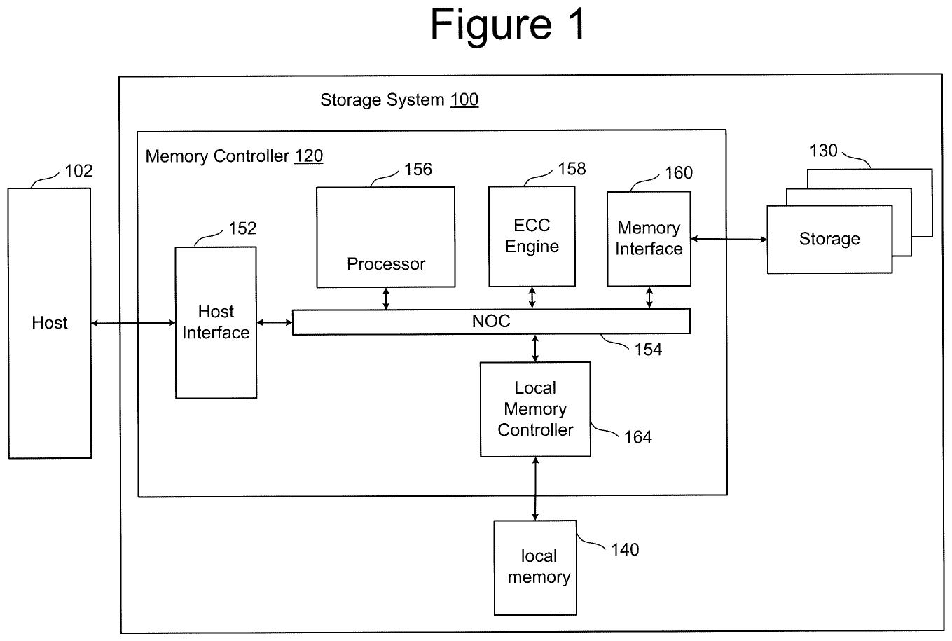

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

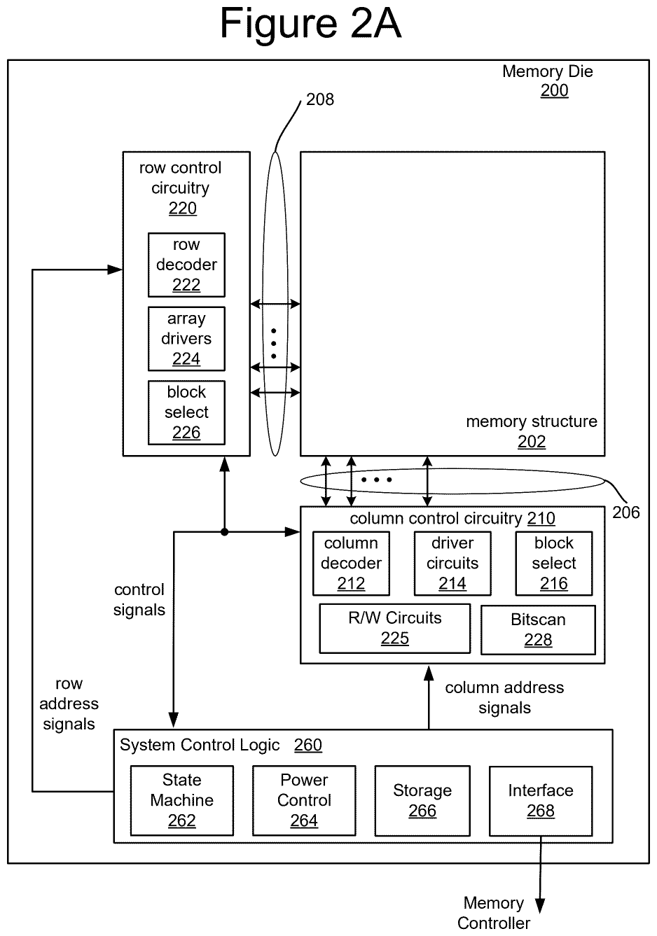

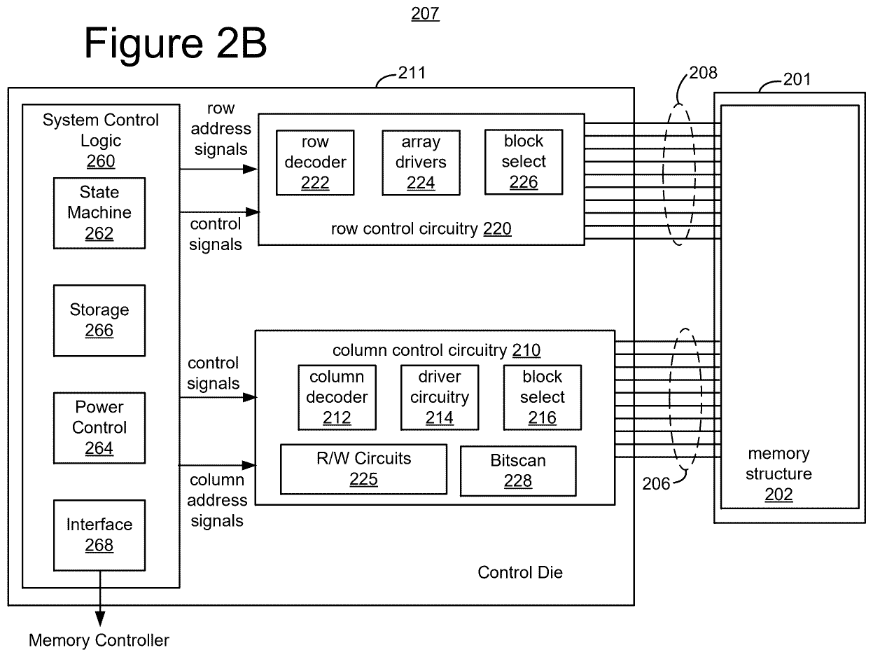

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. The R/W circuits 225 contain data latches. The bitscan logic 228 is able to count the number of data latches having a certain bit value. In some embodiments, the bitscan logic 228 may stop counting if the count of data latches having the certain bit value reaches some target number. The term “bitscan” as used throughout this disclosure means to count bits (having one of either a “1” or “0 ” value) that are present in a set of data latches or the like. A bitscan may stop prior to examining the content of all the data latches if certain number is reached. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuity 220 are configured to control memory operations such as open block reads at the die level.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

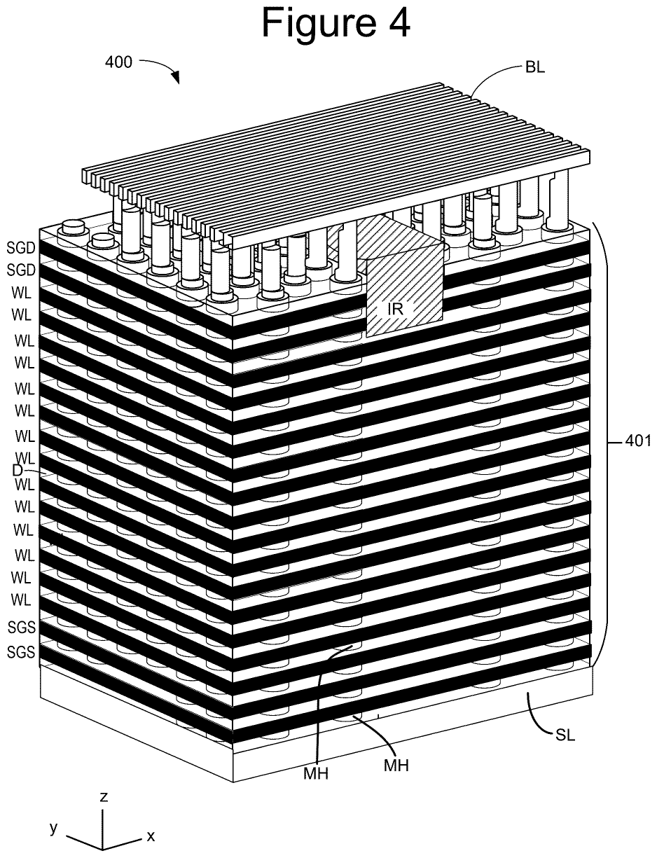

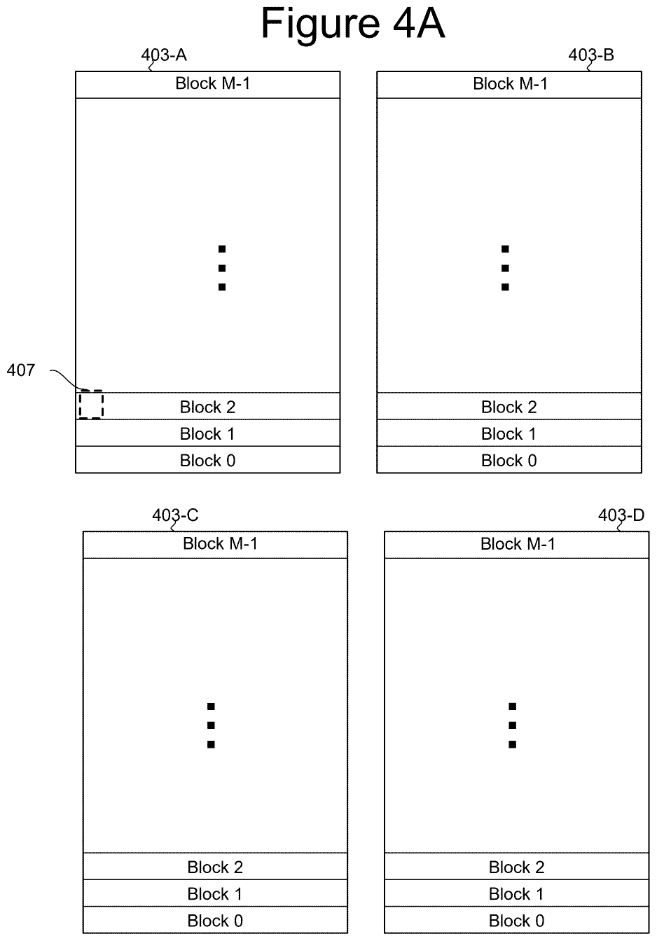

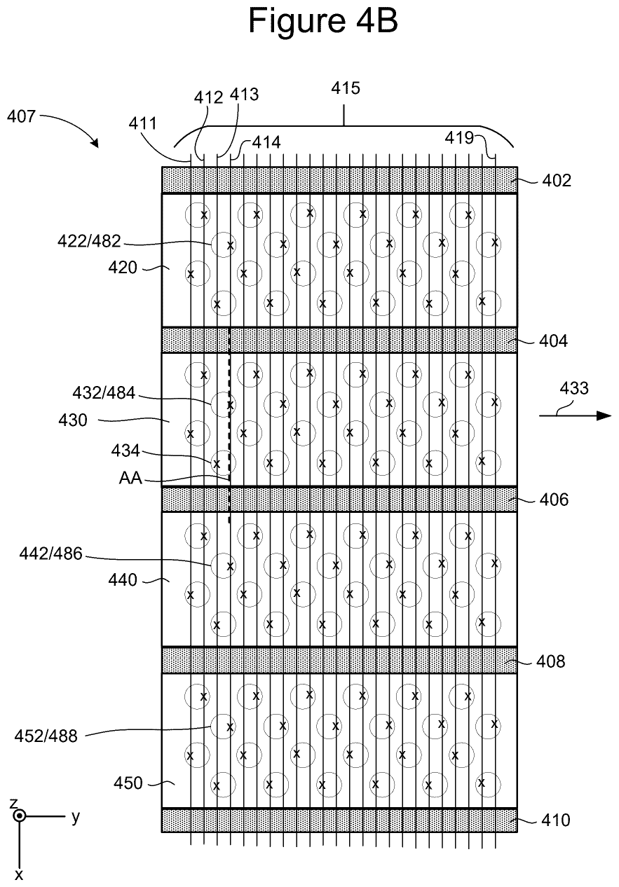

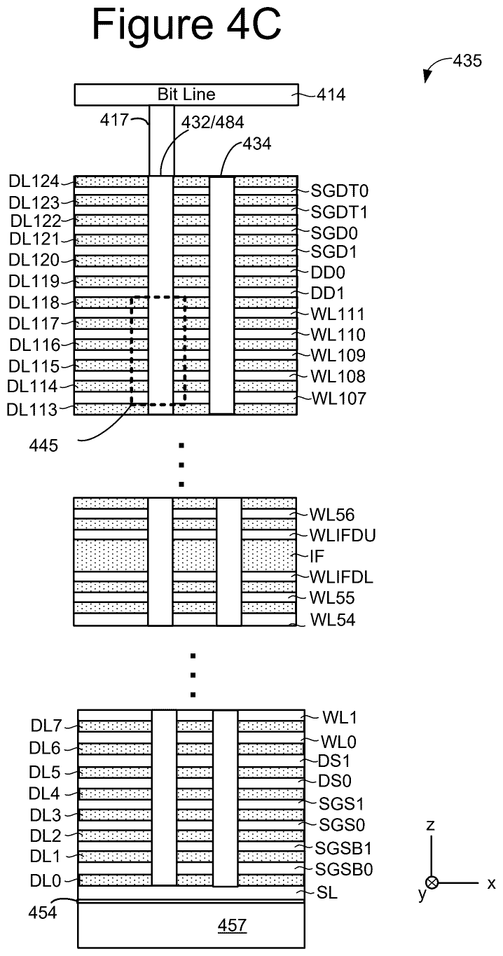

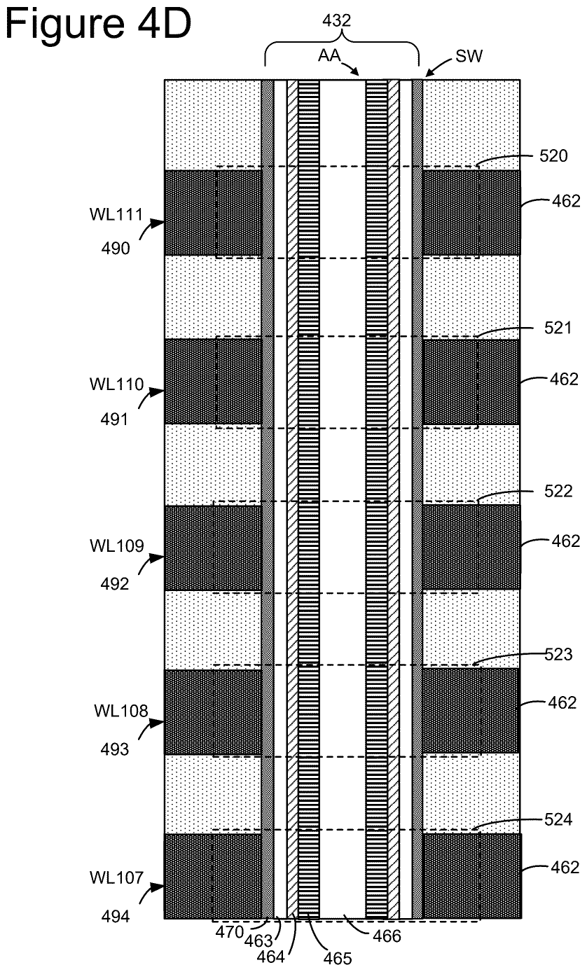

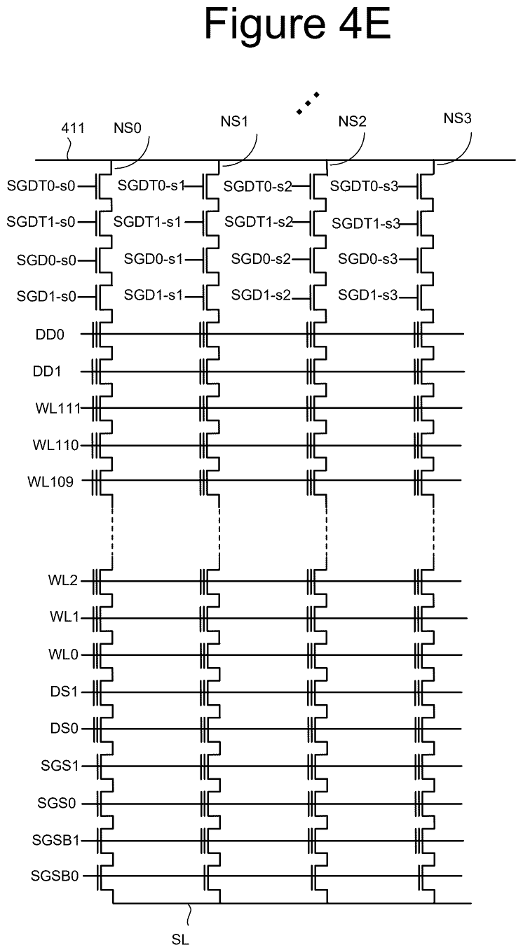

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 211.

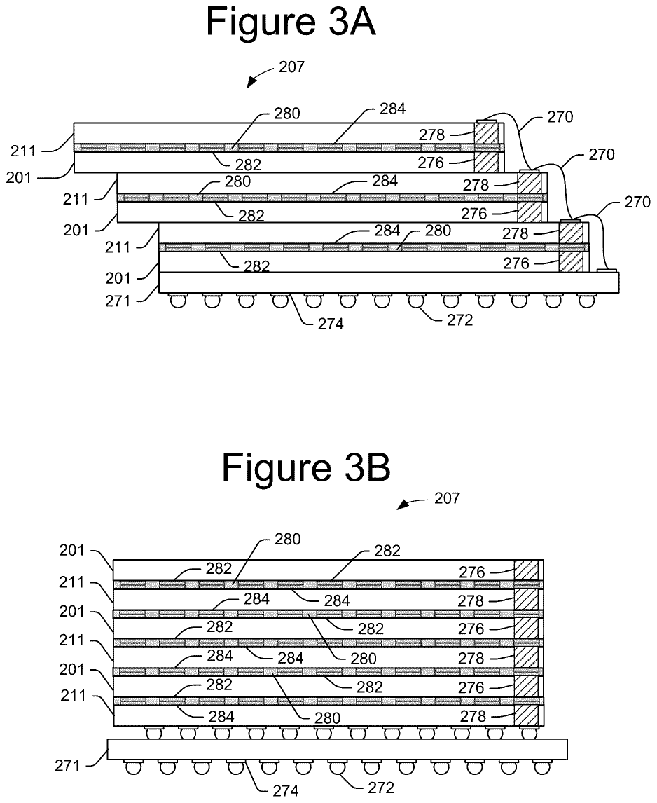

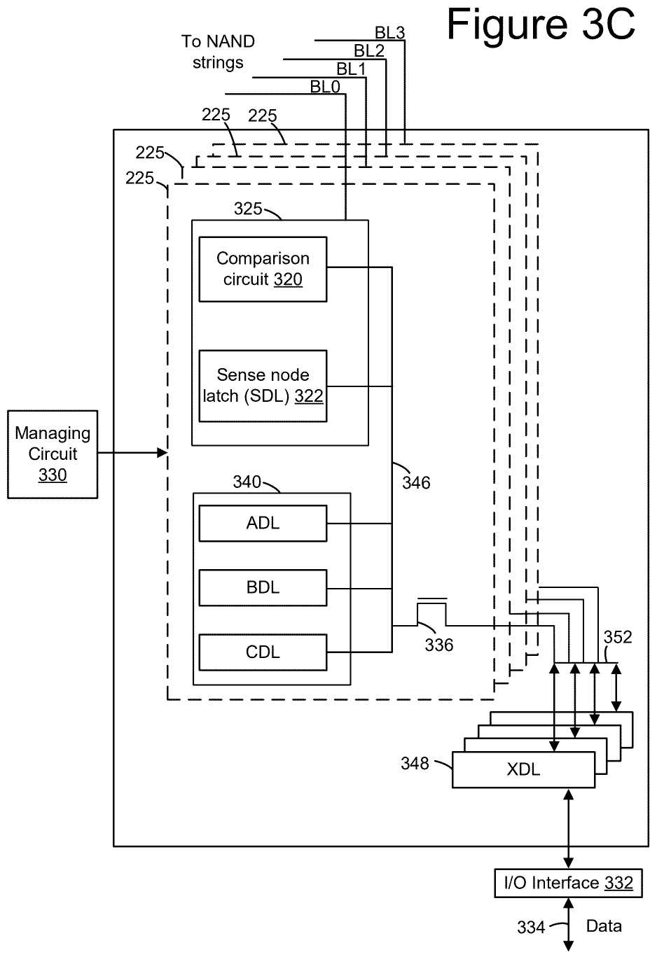

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 3C is a block diagram depicting one embodiment of a portion of column control circuitry 210 that contains a number of read/write circuits 225. Each read/write circuit 225 is partitioned into a sense amplifier 325 and data latches 340. A managing circuit 330 controls the read/write circuits 225. The managing circuit 330 may communicate with state machine 262. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, and read operations. Sense amplifiers are also used to sense the condition (e.g., data state) of a memory cell in a NAND string connected to the bit line that connects to the respective sense amplifier.

Each sense amplifier 325 may have a sense node. During sensing, a sense node (SEN) is charged up to an initial voltage, Vsense_init, such as 3V. The sense node is then connected to the bit line for a sensing time, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time.

In particular, the comparison circuit 320 determines the amount of decay by comparing the sense node voltage to a trip voltage after the sensing time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the program verify voltage. A sense node latch (SDL) 322 is set to 0 or 1, for example, by the comparison circuit 320 based on whether the memory cell is in a conductive or non-conductive state, respectively. The bit in the sense node latch 322 can also be used in a lockout scan to decide whether to set a bit line voltage to an inhibit or a program enable level in a next program loop. The bit in the sense node latch 322 can also be used in a lockout mode to decide whether to set a bit line voltage to a sense voltage or a lockout voltage in a read operation. The sense node latch 322 may also be referred to herein as “SDL”.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Managing circuit 330 performs computations, such as to determine the data stored in the sensed memory cell and store the determined data in the set of data latches. Each set of data latches 340 is used to store data bits determined by managing circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to managing circuit 330. At that point, managing circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. In one embodiment, each program voltage is followed by a verify operation to determine if the memory cells have been programmed to the desired memory state. In some cases, managing circuit 330 monitors the read back memory state relative to the desired memory state. When the two agree, managing circuit 330 sets the bit line in a program inhibit mode such as by updating its latches. This inhibits the memory cell coupled to the bit line from further programming even if additional program pulses are applied to its control gate.

In an embodiment, the managing circuit 330 is able to perform an Exclusive OR (XOR) of the bit line of the SDL latch 322 with the bit value in one of the data latches 340 (e.g., ADL). The managing circuit 330 may store the XOR result into one of the data latches 340 (e.g., ADL). In one embodiment, the bitscan logic 228 is able to count a certain bit value (e.g., “1”) in the data latches (e.g., ADL) having the XOR results. In an embodiment, the bitscan logic 228 may stop the counting if some pre-determined value is reached.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend down through all of the alternating dielectric layers and conductive layers.

FIG. 4A is a block diagram explaining one example organization of memory structure 202, which is divided into four planes 403-A, 403-B, 403-C, 403-D. Each plane is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows four planes 403 more or fewer than four planes can be implemented. In some embodiments, memory structure 202 is an extreme multi-plane architecture with, for example, 32, 64, 128 or some other large number of planes. In some embodiments, programming and reading can be performed in parallel in a selected block in each plane 403.

FIGS. 4B-4E depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks. Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different strings can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, and/or erase).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIFDL, DS1, and DS0 are provided, in addition to the data word line layers WL0-WL111. There may be more or fewer than 112 data word line layers and more or fewer than four dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 414. NAND string 484 has a source-end at a bottom of the stack and a drain-end at a top of the stack. The source-end is connected to the source line SL. A conductive via 417 connects the drain-end of NAND string 484 to the bit line 414.

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

FIG. 4C depicts an example of a stack 435 having two sub-blocks (SB). The two SB stack comprises SB0 and SB1. A two SB or other multi-SB stack can be used to form a relatively tall stack while maintaining a relatively narrow memory hole width (or diameter). After the layers of the lower SB are formed, memory hole portions are formed in the lower SB. Subsequently, after the layers of the upper SB are formed, memory hole portions are formed in the upper SB, aligned with the memory hole portions in the lower SB to form continuous memory holes from the bottom to the top of the stack. The resulting memory hole is narrower than would be the case if the hole were etched from the top to the bottom of the stack rather than in each SB individually. An interface (IF) region is created where the two SBs are connected. The IF region is typically thicker than the other dielectric layers. Due to the presence of the IF region, the adjacent word line layers suffer from edge effects such as difficulty in programming or erasing. These adjacent word line layers can therefore be set as dummy word lines (WLIFDL, WLIFDU).

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running across the entire block. The structure of FIG. 4E corresponds to a portion 407 in Block 2 of FIG. 4A, including bit line 411. Within the physical block, in one embodiment, each bit line is connected to four NAND strings. Thus, FIG. 4E shows bit line 411 connected to NAND string NS0, NAND string NS1, NAND string NS2, and NAND string NS3.

In one embodiment, there are four sets of drain side select lines in the physical block. For example, the set of drain side select lines connected to NS0 include SGDT0-s0, SGDT1-s0, SGD0-s0, and SGD1-s0. The set of drain side select lines connected to NS1 include SGDT0-s1, SGDT1-s1, SGD0-s1, and SGD1-s1. The set of drain side select lines connected to NS2 include SGDT0-s2, SGDT1-s2, SGD0-s2, and SGD1-s2. The set of drain side select lines connected to NS3 include SGDT0-s3, SGDT1-s3, SGD0-s3, and SGD1-s3. Herein the term “SGD” may be used as a general term to refer to any one or more of the lines in a set of drain side select lines. In some embodiments, the same operating voltage is applied to SGDT0 and SGDT1. In some embodiments, the same operating voltage is applied to SGD0 and SGD1. In some erase embodiments, different operating voltage are applied to SGDT0/SGDT1 than to SGD0/SGD1. Note that SGDT0/SGDT1 are adjacent to the bit line. In some erase embodiments, a voltage applied to SGDT0/SGDT1 in combination with a bit line voltage may be used to generate a gate induced gate leakage (GIDL) current. Such a voltage applied to SGDT0/SGDT1 may be referred to herein as a GIDL voltage.

In an embodiment, each line in a given set may be operated independent from the other lines in that set to allow for different voltages to the gates of the four drain side select transistors on the NAND string. Moreover, each set of drain side select lines can be selected independent of the other sets. Each set drain side select lines connects to a group of NAND strings in the block. Only one NAND string of each group is depicted in FIG. 4E. These four sets of drain side select lines correspond to four “sub-blocks.” A first sub-block corresponds to those vertical NAND strings controlled by SGDT0-s0, SGDT1-s0, SGD0-s0, and SGD1-s0. A second sub-block corresponds to those vertical NAND strings controlled by SGDT0-s1, SGDT1-s1, SGD0-s1, and SGD1-s1. A third sub-block corresponds to those vertical NAND strings controlled by SGDT0-s2, SGDT1-s2, SGD0-s2, and SGD1-s2. A fourth sub-block corresponds to those vertical NAND strings controlled by SGDT0-s3, SGDT1-s3, SGD0-s3, and SGD1-s3. As noted, FIG. 4E only shows the NAND strings connected to bit line 411. However, a full schematic of the block would show every bit line and four vertical NAND strings connected to each bit line.

In one embodiment, all of the memory cells on the NAND strings in a physical block are erased as a unit. However, in some embodiments, a physical block is operated as multiple tiers, with each tier containing a contiguous set of word lines. For example, memory cells connected to WL0-WL55 may be in one tier and memory cells connected to WL56-WL111 may be in another tier. A physical block could be operated in more than two tiers. Erase units can be formed based on other divisions of physical blocks.

Although the example memories of FIGS. 4-4E are three dimensional memory structure that includes vertical NAND strings with charge-trapping material, other 3D memory structures can also be used with the technology described herein.

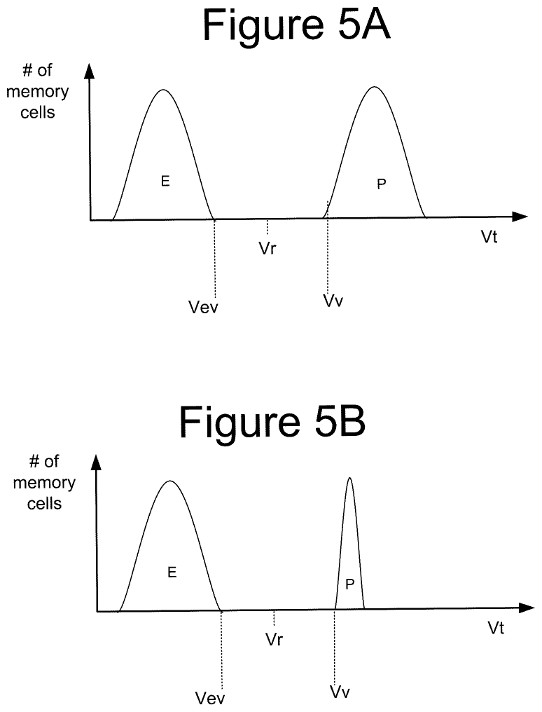

The storage systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data.

FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cells is erased (state E) or programmed (state P). FIG. 5A also depicts program verify reference voltage Vv. In some techniques, when programming memory cells to data state P, the system will test whether those memory cells have a threshold voltage greater than or equal to Vv. However, one conventional technique is to not perform a program verify when programming memory cells to data state P. In one conventional technique the memory system will apply a single program pulse without any verification. This single program pulse has a magnitude such that it is expected that the memory cells that are targeted for the P state will have a Vt significantly above the read reference voltage (Vr). However, since there is no verification some of the P-state memory cells could have a Vt below Vv. Moreover, the P-state threshold voltage distribution is relatively wide. That is, the range in Vt between the upper tail and lower tail of the P-state Vt distribution is relatively large.

FIG. 5B depicts SLC threshold voltage distributions that are programmed by an embodiment of a memory system. Threshold voltage distribution E corresponds to an erased data state. Threshold voltage distribution P corresponds to a programmed data state. An embodiment of a memory system applies a number of program pulses to the memory cells targeted for the P-state with verification performed at the target Vv level. The memory system steps up that magnitude of the program voltage with relatively small step sizes to thereby result in a narrow P-state. That is, the range in Vt between the upper tail and lower tail of the P-state Vt distribution is relatively small. For example, the range in Vt between the upper tail and lower tail of the P-state Vt distribution in FIG. 5B is much smaller than the range in Vt between the upper tail and lower tail of the P-state Vt distribution in FIG. 5A. There may be an upper limit to how many program pulses may be applied prior to a program failure being recorded. In an embodiment, the memory system will allow more than 10 (e.g., 16 pulses) to be applied prior to declaring a program failure. However, the number of allowed program pulses is a matter of design choice.

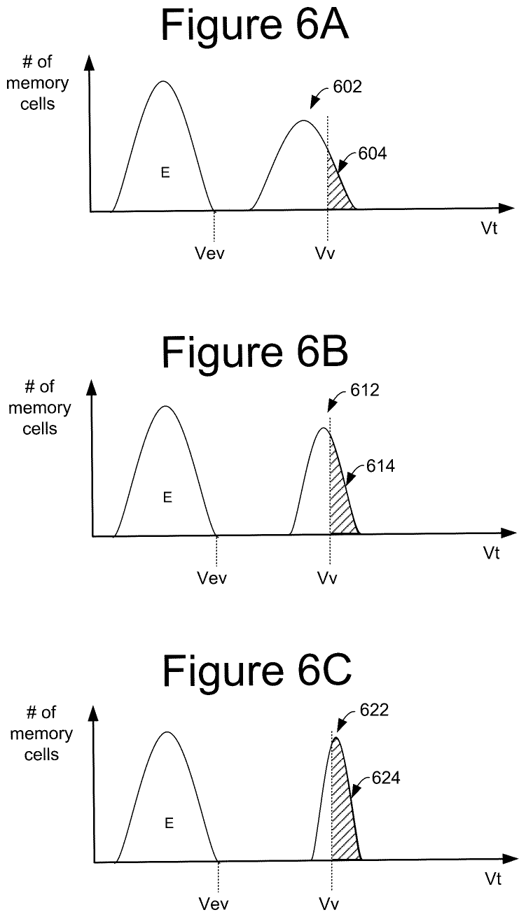

FIGS. 6A, 6B, and 6C depict further details of Vt distributions during programming by an embodiment of a memory system. FIG. 6A shows results after one or more program pulses are applied to the memory cells. The E-state memory cells are inhibited from programming in order to keep their Vts in the E-state. The Vt of a memory cell targeted for the P-state will be increased slightly with each program pulse until the memory cell's Vt reaches the target verify level (Vv), at which point the memory cell is inhibited from further programming (similar to the E-state memory cells) when the next program pulse is applied. Vt distribution 602 is for memory cells targeted for the P-state. Some of the memory cells have a Vt at or above the target verify level (Vv), as indicated by region 604. The memory cells in region 604 will be inhibited from programming for the rest of the SLC programming process.

FIG. 6B shows results after an additional program pulse is applied to the memory cells. Vt distribution 612 is for memory cells targeted for the P-state. The memory cells having a Vt at or above the target verify level (Vv) are indicated by region 614. Significantly, some additional memory cells have had their Vt reach the target verify level (Vv) as a result of the most recent program pulse.

FIG. 6C shows results after a still additional program pulse is applied to the memory cells. Vt distribution 622 is for memory cells targeted for the P-state. The memory cells having a Vt at or above the target verify level (Vv) are indicated by region 624. Significantly, some additional memory cells have had their Vt reach the target verify level (Vv) as a result of the most recent program pulse. After application of one or more additional program pulse the P-state distribution will resemble the P-state distribution of FIG. 5B. Thus, this SLC programming process results in a tight Vt distribution for the P-state.

The speed at which the memory cells in a plane program to the P-state may be impacted by a defect in the plane. An embodiment of a memory system tests the SLC programming speed to determine whether there is a defect in the plane. In an embodiment, if the SLC programming speed is too slow then the memory system terminates the SLC programming early. The memory system may also record that a defect exists in connection with the memory cells being programmed. In one embodiment, the memory system determines that a region (e.g., block) is ineligible for programming if the SLC programming speed is too slow. In one embodiment, the memory system determines the SLC programming speed by determining how many memory cells have their Vt first reach the target verify level (Vv) after a particular program pulse is applied. For example, the memory system could determine how many memory cells have their Vt first reach the target verify level (Vv) after program pulse that resulted in the distributions in FIG. 6B. However, to speed up the counting process the memory system may stop counting after the count reaches a threshold number that indicates SLC programming is sufficiently fast. In one embodiment the memory system compares a count of memory cells in, for example, region 614 with region 604 to determine how many memory cells have their Vt first reach the target verify level (Vv) after program pulse that resulted in the distributions in FIG. 6B. Again, the memory system may stop the count if the count reaches a threshold number that indicates SLC programming is sufficiently fast. Note that the examples in FIG. 6A-6C correspond to applying a few program pulses, but embodiments of SLC programming could have additional program pulses to achieve a tight distribution for the SLC programmed state.

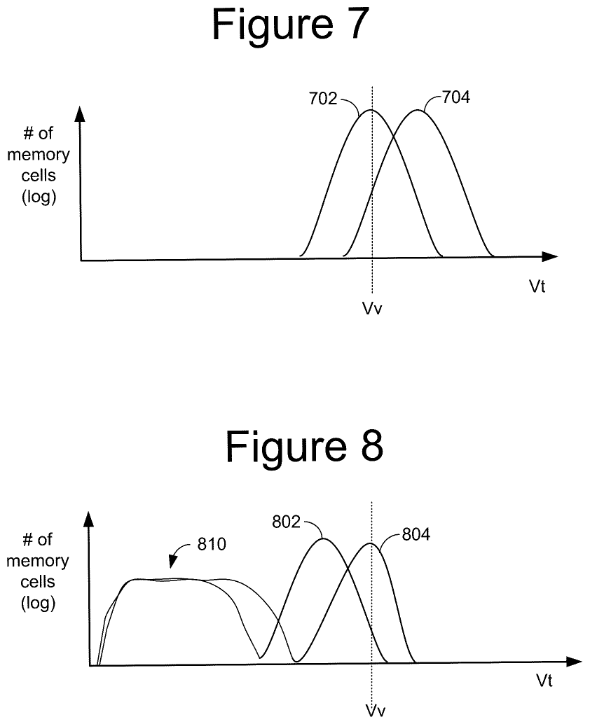

FIG. 7 shows two Vt distributions for an example of programming in a good plane. Vt distribution 702 is the distribution after the nth program pulse, where n is at least one but typically more than one. Vt distribution 704 is the distribution after the nth+1 program pulse. As an example, after the nth pulse about 36,000 memory cells may have a Vth at or above Vv and after the nth+1 pulse about 73,000 memory cells may have a Vt at or above Vv. Therefore, about 37,000 additional memory cells have their Vt reach Vv after the nth+1 program pulse.

FIG. 8 shows two Vt distributions for an example of programming in a bad plane. Vt distribution 802 is the distribution after the nth program pulse, where n is that same number as the example in FIG. 7. Note that only a few memory cells have their Vt reach Vv after the nth program pulse. For example, above two dozen memory cells have their Vt reach Vv after the nth program pulse. Also, a significant number of memory cells in Vt distribution 802 are very slow programming, as pointed out in region 810. Vt distribution 804 is the distribution after the nth+1 program pulse. As an example, after the nth+1 pulse just over 13,000 memory cells may have a Vth at or above Vv. Therefore, about 13,000 additional memory cells have their Vt reach Vv after the nth+1 program pulse. Note that a significant number of memory cells for Vt distribution 804 remain in region 810, which are very slow programming memory cells. The Vt of such very slow programming memory cells may fail to reach Vv within the allotted number of program pulses. These very slow programming memory cells in region 810 could be due to a defect. Such a defect could lead to, for example, leakage current. However, there could be other causes for the slow programming memory cells. Note that not only does this defect cause a significant programming issue in the plane with a defect, but other planes could also have their programming negatively impacted. For example, the defect in the trigger (defective) plane may reduce the magnitude of the program voltage on the good (victim) plane thereby slowing programming in the victim plane.

In an embodiment, the memory system will count the number of memory cells whose Vth first reaches the target verify level (Vv) after a particular program pulse. For example, the memory system may count the number of memory cells whose Vth first reaches the target verify level (Vv) after the nth+1 program pulse, where n is an integer of at least 1. As noted above, the count may stop if it exceeds a threshold number. In an embodiment, if this number is less than a threshold number of cells, then the memory system will terminate programming. The memory system may also mark some region (e.g., the block containing the memory cells) as ineligible for programming. The threshold number of cells may be determined by analyzing, for example, data from good regions of cells and bad regions of cells. As one example, the threshold number of cells may be determined by analyzing, for example, data from good planes of cells and bad planes of cells.

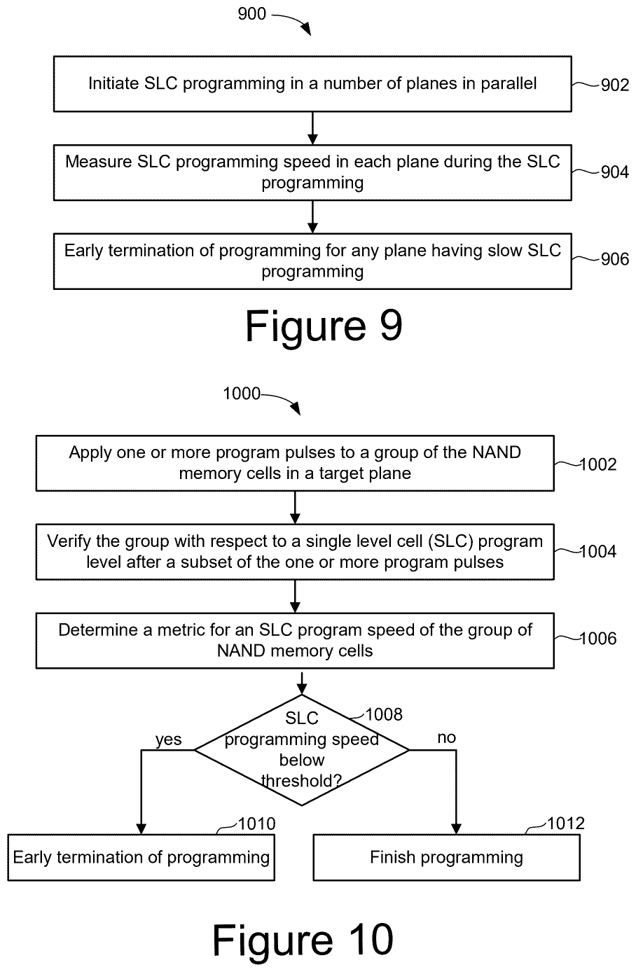

FIG. 9 is a flowchart of one embodiment of a process 900 for early termination of SLC programming. The process 900 may be performed by one or more control circuits that may include, but are not limited to, the memory controller 120, system control logic 260, row control circuitry 220, and/or column control circuitry 210.
Step 902 includes initiating SLC programming in a number of planes in parallel. These planes may be on the same memory die (e.g. memory die 200, memory array die 201). The memory system may program a relatively large number of planes on the memory in parallel. The SLC programming includes applying multiple programming pulses to the memory cells being programmed in each plane. The SLC programming also includes program verify for at least some of the program pulses.
Step 904 includes measuring SLC programming speed in each plane during the SLC programming. The speed measurement may be based on the program verify. Thus, the speed measurement may be performed during SLC programming. In one embodiment, the speed measurement is performed based on the program verify results from two successive program pulses. These two successive program pulses may be pre-determined pulses. In other words, the speed measurement may be based on verify results for the program pulses of pre-determined program loops. The program pulses that are selected for the speed measurement may be based on analysis of SLC programming in good and bad planes.
Step 906 includes early termination of programming for any plane having slow SLC programming. The slow SLC programming could have a detrimental effect on the SLC programming in the other planes. The early termination of SLC programming in the slow programming plane may therefore prevent such detrimental effects on the SLC programming in the other planes.

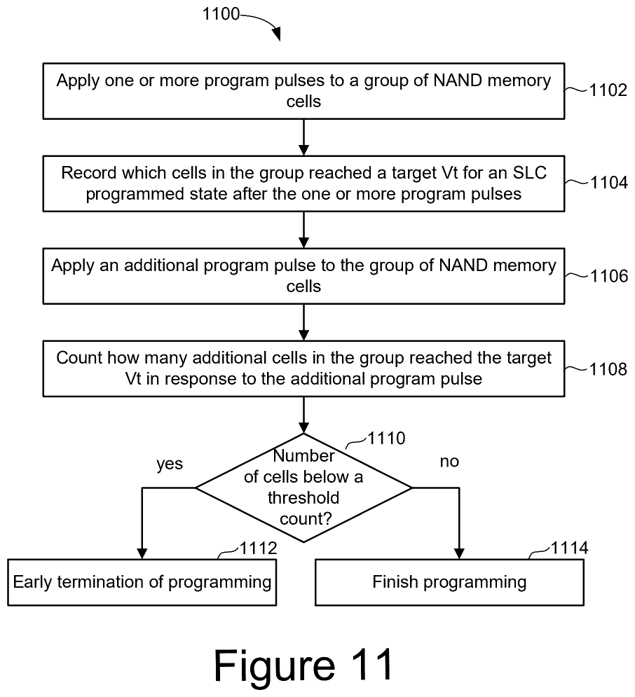

FIG. 10 is a flowchart of one embodiment of a process 1000 for early termination of SLC programming in a target plane. Process 1000 provides further details for EPT in a target plane during SLC programming in multiple planes in parallel. Process 1000 may be performed in parallel for a number of planes. Process 1000 may be performed for each plane in the multiple plane programming process 900 of FIG. 9. The process 1000 may be performed by one or more control circuits that may include, but are not limited to, the memory controller 120, system control logic 260, row control circuitry 220, and/or column control circuitry 210. The steps in process 1000 are described in a certain order to facilitate explanation. However, the steps do not necessarily need to be performed in the exact order depicted in FIG. 10.
Step 1002 includes applying one or more program pulses to a group of NAND memory cells in a target plane. Step 1004 includes verifying the group with respect to a single level cell (SLC) program level after a subset of the one or more program pulses. The term “subset” as used herein with respect to a set of one or program pulses means at least one program pulse in the set and up to all of the program pulses in the set. Thus, the program verify may be performed after each program pulse, but is not required to be performed after each program pulse. Note that steps 1002 and 1004 may alternate (e.g., first program pulse followed by verify, second program pulse followed by verify, etc.).
Step 1006 includes determining a metric for SLC programming speed of the group of memory cells. In an embodiment, the determination is made based on the program verify. In an embodiment, the determination is made based on the program verify results for two successive program pulses. The program speed may be based on a difference in the program verify results for the two successive program pulses. For example, the program speed may be based on how many additional memory cells reach a target SLC program level in response to application of a certain (e.g., “pre-determined”) one of the program pulses.
Step 1008 includes a determination of whether the SLC programming speed is below a threshold. Step 1008 may include determining whether at least some threshold number of cells first reached the target SLC program level in response to application of a pre-determined program pulse. Step 1008 may include performing a bit scan of XOR results as described in connection with FIG. 11. If the SLC programming speed is below the threshold, then in step 1010 programming of terminated early (referred to as “early program termination”). If the SLC programming speed is not below the threshold, the SLC programming is allowed to finish in step 1012. Step 1012 may include applying one or more additional program pulses and verifying whether a sufficient number of memory cells have their Vt reach the target SLC level.

FIG. 11 is a flowchart of one embodiment of a process 1100 for early termination of SLC programming in a target plane. Process 1100 provides further details for EPT in a target plane during SLC programming in multiple planes in parallel. Process 1100 may be performed in parallel for a number of planes. Process 1100 may be performed for each plane in the multiple plane programming process 900 of FIG. 9. The process 1100 may be performed by one or more control circuits that may include, but are not limited to, the memory controller 120, system control logic 260, row control circuitry 220, and/or column control circuitry 210. The steps in process 1000 are described in a certain order to facilitate explanation. However, the steps do not necessarily need to be performed in the exact order depicted in FIG. 11.
Step 1102 includes applying one or more program pulses to a group of NAND memory cells in a target plane. Step 1104 recording which memory cells in the group reached a target Vt for an SLC programmed state after the one or more program pulses. Step 1104 may include the results for each cell in a data latch associated with that cell. For example, the ALD latches (see FIG. 3C) may be used to record which memory cells in the group reached the target Vt, [symbol]
Step 1106 includes applying an additional program pulse to the group of NAND memory cells. Step 1108 includes a count of how many additional NAND memory cells in the group reached the target Vt in response to the additional program pulse. This count may be referred to as a bitscan. The bitscan may end if the count reaches a certain number that indicates that the SLC programming is not slow. Therefore, a complete count of all cells that reached the target Vt in response to the additional program pulse is not required.
Step 1110 includes a determination of whether number of memory cells is below a threshold count. If the number of memory cells is below the threshold count, then in step 1112 programming is terminated early. If the number of memory cells is not below the threshold count, the SLC programming is allowed to finish in step 1114. Step 1114 may include applying zero or more additional program pulses and verifying whether a sufficient number of memory cells have their Vt reach the target SLC level.

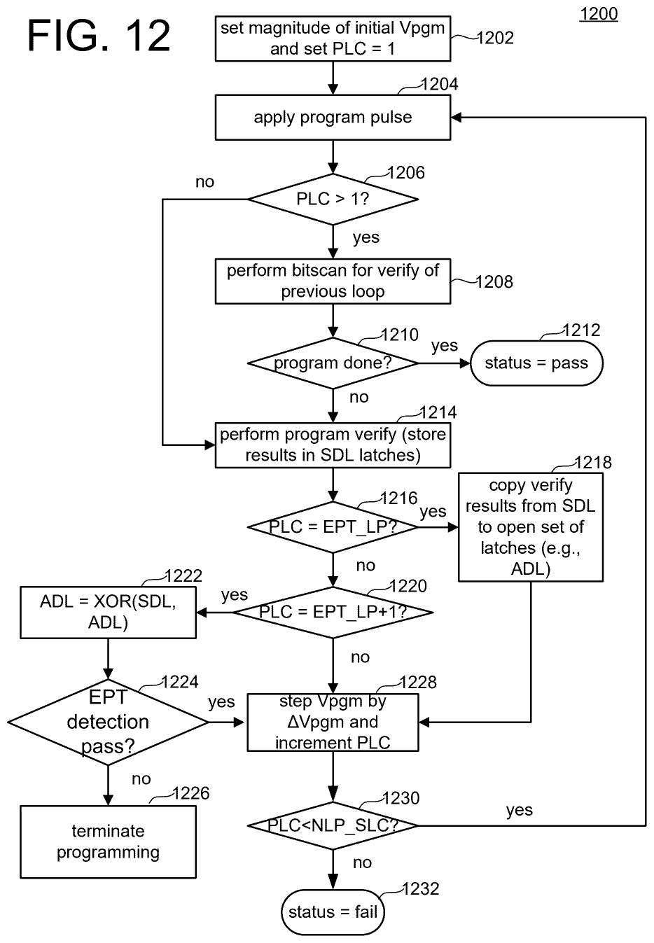

FIG. 12 is a flowchart of one embodiment of a process 1200 for early termination of SLC programming in a target plane. Process 1200 provides further details for EPT in a target plane during SLC programming in multiple planes in parallel. Process 1200 may be performed in parallel for a number of planes. Process 1200 may be performed for each plane in the multiple plane programming process 900 of FIG. 9. The process 1200 may be performed by one or more control circuits that may include, but are not limited to, the memory controller 120, system control logic 260, row control circuitry 220, and/or column control circuitry 210. The steps in process 1000 are described in a certain order to facilitate explanation. However, the steps do not necessarily need to be performed in the exact order depicted in FIG. 12.
Step 1202 includes setting the magnitude of the initial program pulse (Vpgm). A program loop counter (PLC) is also initialized to 1. Step 1204 includes applying a program pulse to a group of NAND memory cells in a target plane.
Step 1206 includes a test of whether the PLC is greater than one. If the PLC is not greater than one then the memory system skips steps 1208-1212. If the PLC is greater than one, then the memory system analyzes program verify results for the previous program loop. Step 1208 includes a bitscan of the program verify results from the previous program pulse. The bitscan includes a count of memory cells that have not yet reached the target Vt for the SLC program state. Step 1210 include a determination of whether programmed in done. The programming is considered complete if the bitscan count is less than a pre-defined number. The pre-defined number may be set to allow completion of programming even though a few memory cells fail to reach the target Vt. If the SLC programming is complete, then in step 1212 a status of pass is reported. The memory die (or control die) may report this status to the memory controller 120.

If the SLC programming is not complete, then program verify is performed in step 1214. Program verify includes applying a verify reference voltage to the memory cells (e.g., to the selected word line) and testing the current of the respective memory cells. The magnitude of the cell current may be tested by discharging a capacitor for a sense time and then testing the voltage on the capacitor. Memory cells whose Vt has still not reached the target Vt will conduct a sufficiently large current to discharge the capacitor to voltage below a trip point. The current for memory cells whose Vt has reached the target Vt will not be large enough to discharge the capacitor to the voltage below the trip point. A sense data latch (SDL) is set based on the magnitude of the voltage on the sense capacitor. As one example, the SDL latch may be set to “1” if the memory cell's Vt is still below the target voltage for the SLC program state and set to “0” if the memory cell's Vt has reached the target voltage for the SLC program state.
Step 1216 includes a test of whether the program loop count (PLC) is equal to a count for an early program termination test loop count (EPT_LP). If PLC=EPT_LP, then in step 1218 the results from the SDL latches are copied to a set of free latches. As one example, the results from the SDL latches could be copied to the ADL latches (however, a different set of latches could be used). After step 1218 the program voltage (Vpgm) is stepped up by a program voltage step size (ΔVpgm) and the PLC is incremented in step 1228. In step 1230 the program loop count (PLC) is compared to a loop count guard band for SLC programming (NLP_SLC). If PLC<NLP_SLC, then another program loop may be performed by returning to step 1204. Otherwise, programming is terminated with a status of fail in step 1232. The fail status may be reported to the memory controller 120.

Returning again to the discussion of step 1216, recall that this step compares the program loop count (PLC) with an early program termination test loop count (EPT_LP). If PLC does not equal EPT_LP then in step 1220 the memory system tests whether PLC=EPT_LP+1. In other words, step 1220 is a test of whether this program loop is the loop that immediately follows the loop in which the content of the SDL latches were transferred to the ADL latches (step 1218). If PLC=EPT_LP+1, then in step 1222 the contents of the ADL latches is set to an XOR of the present content of the SDL latches and the content of the ADL latches. Note that this is equivalent to an XOR of the contents of the SDL latches from two successive program loops. The contents of the ADL latches will indicate how many additional memory cells have their Vt reach the target voltage for the SLC programmed state with the most recent program pulse. Step 1224 is a determination of whether EPT detection passed. Step 1224 may include a count of the additional memory cells have their Vt reach the target voltage for the SLC programmed state with the most recent program pulse. This count may be made by scanning the contents of the ADL latches. The scan may stop if the count reaches a number that indicates SLC programming is sufficiently fast. In one embodiment, the ADL latch will contain a “1” if the memory cell first reached the target SLC program state with the most recent program pulse. In an embodiment if this count is sufficiently high then the EPT detection passes. EPT detection passed means that programming should continue (at step 1228, which has previously been discussed). In an embodiment if this count is lower than a predetermined number then the EPT detection fails. EPT detection fails means that the SLC programming in this plane is terminated early (step 1226). The memory system, however, will continue to program in other planes (assuming EPT detection passes in those planes).

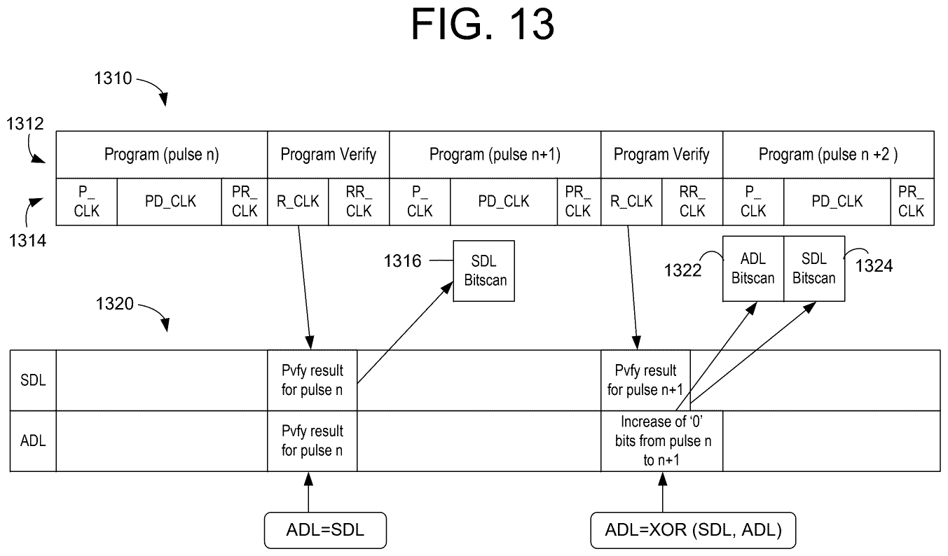

Note that the order of the steps in FIG. 12 is presented to facilitate explanation. However, the steps could be performed in a different order. Also, some steps may be performed together. For example, the bitscan in step 1208 could be performed while applying the program pulse in step 1204. The EPT test could be performed at other times relative to the other steps in process 1200. FIG. 13 illustrates latch usage during an embodiment of SLC programming. Table 1310 contains a row 1312 that identifies either a program pulse or a program verify that occurs during that time period. The program phase for three consecutive program pulses are listed (pulse n, pulse n+1, pulse n+2). Row 1314 in table 1310 describes the “sub-clocks” that occur for a program phase or a verify phase. For example, for each program phase there is a P_CLK, PD_CLK, and PR_CLK. During the P_CLK the memory system may set up voltages on unselected word lines and other control lines prior to applying the program pulse on the selected word line. The voltage on the selected word line may be raised partially towards the program voltage during the P_CLK. The PD_CLK may correspond to applying the program pulse to the selected word line. The PR_CLK may be used during a recovery stage (e.g., ramping down voltages). The PD_CLK is typically longer than the P_CLK and the PR_CLK. For each verify phase there is an R_CLK and an RR_CLK. The R_CLK may correspond to when sensing is performed. The RR_CLK may be for a read recovery stage. Table 1320 shows usage for the SDL latch and the ADL latch for a memory cell.

In this example, the program verify results for pulse n are stored in the SDL latch during the R_CLK of the program verify phase that immediately follows the program phase having program pulse n. The contents of the SDL latch may also be copied to the ADL latch during this R_CLK. The notation ADL=SDL refers to the copying of the contents of SDL to ADL after the SDL contains the verify result. A first SDL bitscan 1316 is performed during the PD_CLK of program pulse n+1. This first SDL bitscan 1316 scans the contents of the SDL latches that were stored as a result of the program verify for program pulse n. The bitscan 1316 may stop further counting if the count reaches a number that indicates programming is not yet complete.

The program verify results for pulse n+1 are stored in the SDL latches during the R_CLK of the program verify phase that immediately follows the program phase having program pulse n+1. Also, after the contents of the SDL latches are set, the ADL latch content is updated to contain the XOR of the present SDL content and the ADL content that was previously stored. The notation ADL=XOR (SDL, ADL) refers to the modifying of the contents of ADL. The net result is that the ADL latches indicate how many additional memory cells have their Vt reach the target verify level as a result of program pulse n+1. In this example, a ‘0’ bit is a bit that has reached the SLC programmed state. Thus, the phrase “increase of ‘0’ bits” means how many additional memory cells have reached the SLC programmed state.

An ADL bitscan 1322 is performed during the P_CLK of program pulse n+2. The ADL bitscan 1322 scans the contents of the ADL latches. The ADL bitscan 1322 results may be used to determine whether the EPT detection passes. The ADL bitscan 1322 may stop counting if the number reaches a count that indicates SLC programming is sufficiently fast. The second SDL bitscan 1324 scans the contents of the SDL latches that were stored as a result of the program verify for program pulse n+1. The second SDL bitscan 1324 results may be used to determine whether programming is complete. Note that the ADL bitscan 1322 may be “hidden” in the P_CLK such that the program phase need not be extended in time. That is, the second SDL bitscan 1324 can take place in the PD_CLK similar to how the first SDL bitscan 1316 took place in the PD_CLK of the previous program pulse.

Numerous modifications to the timings in FIG. 13 are possible. One modification is to place both the ADL bitscan 1322 and the second SDL bitscan 1324 into the PD_CLK of program pulse n+2. Another modification is to allow the second SDL bitscan 1324 to extend into the PR_CLK of program pulse n+2 in the event that both the ADL bitscan 1322 and the second SDL bitscan 1324 are not able to fit timewise into the PD_CLK of program pulse n+2. Also, the ADL bitscan 1322 could start in the P_CLK of program pulse n+2 but finish in the PD_CLK of program pulse n+2. The example in FIG. 13 and the foregoing and other potential modifications allow the ADL bitscan 1322 to be performed without any penalty to the program time (Tprog).

In view of the foregoing, an embodiment includes an apparatus comprising one or more control circuits configured to connect to a semiconductor die having a plurality of planes of NAND memory cells. The one or more control circuits are configured to apply a plurality of program pulses to a group of the NAND memory cells in a target plane of the plurality of planes during a single level cell (SLC) programming operation that includes program verify. The one or more control circuits are configured to determine a metric for an SLC program speed of the group of NAND memory cells during the SLC programming operation. The one or more control circuits are configured to terminate programming of the group of the NAND memory cells in the target plane responsive to the metric indicating that the SLC program speed is slower than a threshold.

In an embodiment of the apparatus the one or more control circuits are further configured to continue with the SLC programming operation in the target plane responsive to the metric indicating that the SLC program speed is at least as fast as the threshold.

In an embodiment of the apparatus the one or more control circuits are configured to determine the metric for the SLC program speed of the group of NAND memory cells based on the program verify for two successive program pulses of the plurality of program pulses.

In an embodiment of the apparatus the metric comprises a count of how many of the NAND memory cells in the group have their threshold voltage (Vt) first reach an SLC program level following application of a pre-determined program pulse in a sequence of the plurality of program pulses.

In an embodiment of the apparatus the one or more control circuits are configured to store first verification results following a first pre-determined program pulse of the plurality of program pulses into a first set of data latches. The one or more control circuits are configured to store second verification results following a second pre-determined program pulse of the plurality of program pulses that immediately follows the first pre-determined program pulse in a sequence of the plurality of program pulses into a second set of data latches. The one or more control circuits are configured to compare the first verification results with the second verification results to determine the metric.

In an embodiment of the apparatus the one or more control circuits are configured to compare the first verification results with the second verification results during a program phase that includes applying a third pre-determined program pulse to the group of NAND memory cells. The third pre-determined program pulse that immediately follows the second pre-determined program pulse in the sequence of the plurality of program pulses.

In an embodiment of the apparatus the one or more control circuits are configured to store first verification results following a first pre-determined program pulse of the plurality of program pulses into a first set of data latches. The one or more control circuits are configured to store second verification results following a second pre-determined program pulse that immediately follows the first pre-determined program pulse in a sequence of the plurality of program pulses into a second set of data latches. The one or more control circuits are configured to perform a latch by latch Exclusive OR (XOR) of the first verification results in the first set of data latches with the second verification results in the second set of data latches to determine the metric.

In an embodiment of the apparatus the one or more control circuits are configured to store first verification results following a first pre-determined program pulse of the plurality of program pulses into a first set of data latches. The one or more control circuits are configured to transfer the first verification results into a second set of data latches. The one or more control circuits are configured to store second verification results following a second pre-determined program pulse that immediately follows the first pre-determined program pulse in a sequence of the plurality of program pulses into the first set of data latches. The one or more control circuits are configured to perform a latch by latch Exclusive OR (XOR) of the first verification results in the first set of data latches with the second verification results in the second set of data latches. The one or more control circuits are configured to record the latch by latch XOR as the metric. In an embodiment, the latch by latch XOR results are recorded in the second set of data latches; however, the latch by latch XOR results could be recorded in a different set of data latches.

In an embodiment of the apparatus the one or more control circuits are configured to perform a bitscan of the recorded XOR results during a program phase that follows an immediate prior program phase in which the second pre-determined program pulse is applied to determine whether the SLC program speed is slower than the threshold.

In an embodiment of the apparatus the one or more control circuits are configured to perform the SLC programming operation in parallel on groups of NAND memory cells in a set of the plurality of planes in parallel. The one or more control circuits are configured to continue to program the groups of NAND memory cells in other planes in the set of the plurality of planes after terminating the programming of the group in the target plane responsive to the metric indicating that the SLC program speed the target plane is slower than the threshold.

An embodiment includes a method comprising applying one or more program voltages to a group of NAND memory cells in each of a plurality of planes that include a trigger plane and a number of victim planes. The method comprises recording, for each of the plurality of planes, which of the NAND memory cells in the group reached a target threshold voltage for a single level cell (SLC) programmed state after applying the one or more program voltages. The method comprises applying, for each of the plurality of planes, an additional program voltage to the group of the NAND memory cells following applying the one or more program voltages. The method comprises terminating programming of the group of NAND memory cells in the trigger plane responsive to fewer than a threshold number of additional memory cells in the group reaching the target threshold voltage for the SLC programmed state as a result of applying the additional program voltage to the group in the trigger plane. The method comprises continuing the SLC programming to completion in the victim planes responsive to at least the threshold number of additional memory cells in the groups in the victim planes reaching the target threshold voltage for the SLC programmed state as a result of applying the additional program voltage to the groups in the victim planes.

An embodiment includes a non-volatile memory system comprising a memory die having a plurality of planes having NAND memory cells and one or more control circuits in communication with the plurality of planes. The one or more control circuits are configured to initiate single level cell (SLC) programming in multiple planes of the plurality of planes in parallel, the SLC programming comprises applying a plurality of program voltages to selected NAND memory cells in the multiple planes. The one or more control circuits are configured to measure SLC programming speed in each respective plane of the multiple planes based on SLC program verification results in the respective planes. The one or more control circuits are configured to terminate the SLC programming early in any plane having an SLC programming speed slower than a threshold. The one or more control circuits are configured to continue the SLC programming in each plane having an SLC programming speed at least as fast at the threshold.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects. For example, a “set of reference voltages” may contain one or more reference voltages.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a semiconductor die having a plurality of planes of NAND memory cells, the one or more control circuits configured to:
apply a plurality of program pulses to a group of the NAND memory cells in a target plane of the plurality of planes during a single level cell (SLC) programming operation that includes program verify;
determine a metric for an SLC program speed of the group of NAND memory cells during the SLC programming operation; and
terminate programming of the group of the NAND memory cells in the target plane responsive to the metric indicating that the SLC program speed is slower than a threshold.

2. The apparatus of claim 1, wherein the one or more control circuits are further configured to continue with the SLC programming operation in the target plane responsive to the metric indicating that the SLC program speed is at least as fast as the threshold.

3. The apparatus of claim 1, wherein the one or more control circuits are configured to determine the metric for the SLC program speed of the group of NAND memory cells based on the program verify for two successive program pulses of the plurality of program pulses.

4. The apparatus of claim 1, wherein the metric comprises a count of how many of the NAND memory cells in the group have their threshold voltage (Vt) first reach an SLC program level following application of a pre-determined program pulse in a sequence of the plurality of program pulses.

5. The apparatus of claim 1, wherein the one or more control circuits are configured to:
store first verification results following a first pre-determined program pulse of the plurality of program pulses into a first set of data latches;
store second verification results following a second pre-determined program pulse of the plurality of program pulses that immediately follows the first pre-determined program pulse in a sequence of the plurality of program pulses into a second set of data latches; and
compare the first verification results with the second verification results to determine the metric.

6. The apparatus of claim 5, wherein the one or more control circuits are configured to compare the first verification results with the second verification results during a program phase that includes applying a third pre-determined program pulse to the group of NAND memory cells, the third pre-determined program pulse immediately following the second pre-determined program pulse in the sequence of the plurality of program pulses.

7. The apparatus of claim 1, wherein the one or more control circuits are configured to:
store first verification results following a first pre-determined program pulse of the plurality of program pulses into a first set of data latches;
store second verification results following a second pre-determined program pulse that immediately follows the first pre-determined program pulse in a sequence of the plurality of program pulses into a second set of data latches; and
perform a latch by latch Exclusive OR (XOR) of the first verification results in the first set of data latches with the second verification results in the second set of data latches to determine the metric.

8. The apparatus of claim 1, wherein the one or more control circuits are configured to:
store first verification results following a first pre-determined program pulse of the plurality of program pulses into a first set of data latches;
transfer the first verification results into a second set of data latches;
store second verification results following a second pre-determined program pulse that immediately follows the first pre-determined program pulse in a sequence of the plurality of program pulses into the first set of data latches;
perform a latch by latch Exclusive OR (XOR) of the first verification results in the first set of data latches with the second verification results in the second set of data latches; and
record the latch by latch XOR as the metric.

9. The apparatus of claim 8, wherein the one or more control circuits are configured to:
perform a bitscan of the recorded XOR results during a program phase that follows an immediate prior program phase in which the second pre-determined program pulse is applied to determine whether the SLC program speed is slower than the threshold.

10. The apparatus of claim 1, wherein the one or more control circuits are configured to:
perform the SLC programming operation in parallel on groups of NAND memory cells in a set of the plurality of planes in parallel; and
continue to program the groups of NAND memory cells in other planes in the set of the plurality of planes after terminating the programming of the group in the target plane responsive to the metric indicating that the SLC program speed the target plane is slower than the threshold.

11. A method comprising:
applying one or more program voltages to a group of NAND memory cells in each of a plurality of planes that include a trigger plane and a number of victim planes;
recording, for each of the plurality of planes, which of the NAND memory cells in the group reached a target threshold voltage for a single level cell (SLC) programmed state after applying the one or more program voltages;
applying, for each of the plurality of planes, an additional program voltage to the group of the NAND memory cells following applying the one or more program voltages;
terminating programming of the group of NAND memory cells in the trigger plane responsive to fewer than a threshold number of additional memory cells in the group reaching the target threshold voltage for the SLC programmed state as a result of applying the additional program voltage to the group in the trigger plane; and
continuing the SLC programming to completion in the victim planes responsive to at least the threshold number of additional memory cells in the groups in the victim planes reaching the target threshold voltage for the SLC programmed state as a result of applying the additional program voltage to the groups in the victim planes.

12. The method of claim 11, wherein recording which of the NAND memory cells in the group in the trigger plane reached the target threshold voltage for the SLC programmed state after applying the one or more program voltages includes:
storing first verification results following the one or more program voltages into a first set of data latches associated with the trigger plane; and
transferring the first verification results into a second set of data latches associated with the trigger plane.

13. The method of claim 12, further comprising:
storing second verification results following the additional program voltage into the first set of data latches; and
determining whether fewer than the threshold number of additional memory cells in the group in the trigger plane reached the target threshold voltage for the SLC programmed state as a result of applying the additional program voltage to the group by comparing the second verification results in the first set of data latches with the first verification results in the first set of data latches.

14. The method of claim 13, wherein comparing the second verification results in the first set of data latches with the first verification results in the first set of data latches comprises:
performing a latch by latch Exclusive OR (XOR) of content of the first set of data latches and content of the second set of data latches.

15. The method of claim 13, wherein:
the additional program voltage is applied in a program phase that is followed by a verification phase; and
transferring the first verification results into the second set of data latches is performed in the verification phase.

16. The method of claim 13, wherein:
the one or more program voltages are applied during a corresponding one or more program phases;
the additional program voltage is applied during an additional program phase that follows the one or more program phases; and
comparing the second verification results in the first set of data latches with the first verification results in the first set of data latches is performed in a still additional program phase that follows the additional program phase.

17. A non-volatile memory system comprising:
a memory die having a plurality of planes having NAND memory cells; and
one or more control circuits in communication with the plurality of planes, the one or more control circuits configured to:
initiate single level cell (SLC) programming in multiple planes of the plurality of planes in parallel, the SLC programming comprises applying a plurality of program voltages to selected NAND memory cells in the multiple planes;
measure SLC programming speed in each respective plane of the multiple planes based on SLC program verification results in the respective planes;
terminate the SLC programming early in any plane having an SLC programming speed slower than a threshold; and
continue the SLC programming in each plane having an SLC programming speed at least as fast at the threshold.

18. The non-volatile memory system of claim 17, wherein the one or more control circuits are further configured to:
measure SLC programming speed in a particular plane of the respective planes based on a number of the NAND memory cells being programmed in the particular plane that first reach a target single level cell (SLC) program level after a pre-determined program voltage of the plurality of program voltages; and
terminate the SLC programming in the particular plane responsive to the number being below a threshold.

19. The non-volatile memory system of claim 18, wherein the one or more control circuits are further configured to:
store first verification results for a particular plane of the respective planes following a program voltage that immediately precedes a pre-determined program voltage in a sequence of the plurality of program voltages into a first set of data latches associated with the particular plane;
transfer the first verification results into a second set of data latches associated with the particular plane;
store second verification results following the pre-determined program voltage into the first set of data latches; and
compare the first verification results in the first set of data latches with the second verification results in the second set of data latches to determine whether a number of the memory cells in the particular plane that first reach the target single level cell (SLC) program level after the pre-determined program voltage is at least a threshold number.

20. The non-volatile memory system of claim 17, wherein the one or more control circuits are further configured to:
store first verification results following a program voltage that immediately precedes a pre-determined program voltage in a sequence of the plurality of program voltages into a first set of data latches associated with a particular plane of the respective planes;
transfer the first verification results into a second set of data latches associated with the particular plane;
store second verification results following the pre-determined program voltage into the first set of data latches; and
perform a latch by latch Exclusive OR (XOR) of the first verification results in the first set of data latches with the second verification results in the second set of data latches to record which of the memory cells in the particular plane first reach a target single level cell (SLC) program level after the pre-determined program voltage.
